(19) United States
(12) Patent Application Publication
(10) Pub. No.: US 2005/0170653 A1
(43) Pub. Date: Aug. 4, 2005

(54) Semiconductor manufacturing method and apparatus

(75) Inventors: Hiroshi Horiuchi, Koriyama (JP); Toshiyuki Karasawa, Kawasaki (JP); Motoshu Miyajima, Kawasaki (JP); Tamotsu Yamamoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/088,976

(22) Filed: Mar. 24, 2005

Related U.S. Application Data
(63) Continuation of application No. PCT/JP03/00023, filed on Jan. 6, 2003.

(51) Int. Cl. H01L 21/302; H01L 21/461

(52) U.S. Cl. 438/689

(57) ABSTRACT

A method of manufacturing a semiconductor device, comprising the steps of washing the surface of a substrate having insulation areas and metal areas exposed to the surface by using organic cleaning solvent, and radiating ultra-violet ray on the surface of the washed substrate, whereby the accumulation of a residue on the surface of the substrate can be suppressed.

### CROSS REFERENCE TO RELATED APPLICATION

This application is a Continuation Application of PCT/JP2003/000023 filed on Jan. 6, 2003, the entire contents of which are incorporated herein by reference.

### TECHNICAL FIELD

The present invention relates to a semiconductor device manufacturing method and apparatus, and more particularly to a semiconductor device manufacturing method and apparatus by which a wiring is formed by filling a recess formed in an insulating film with metal.

### BACKGROUND ART

Recently, with speeding up of a large scale integrated circuit device (LSI), a delay of an electric signal transmitting through wirings interconnecting electronic circuits in the LSI chip discourages an operation of the LSI from speeding up its operation. Improving the reliability of wirings is another important issue, and copper (Cu) has been paid attention as the wiring material to be replaced with conventional aluminum (Al). When copper is used as the wiring material, a damascene method has been used because it is difficult to etch a copper film.

Brief description will be made on a method of forming a copper wiring by a conventional damascene method. A wiring trench is formed through an interlayer insulating film formed on a semiconductor substrate. A barrier metal layer is formed covering the inner surface of the wiring trench and the upper surface of the interlayer insulating film. A copper seed layer is formed on the surface of the barrier metal layer, and the wiring trench is filled with copper by plating copper.

Unnecessary copper film and barrier metal layer on the interlayer insulating film are removed by chemical mechanical polishing (CMP) to expose the surface of the interlayer insulating film. In this manner, a copper wiring is left in the wiring trench. After CMP, the substrate surface is washed with ammonium, alkaline chemicals such as organic alkaline, or organic acid, and thereafter dried (for example, Japanese Patent Laid-open Publication No. HEI-11-330023).

### DISCLOSURE OF THE INVENTION

Immediately after the substrate surface is dried, no residue or the like is not observed and it appears like a clean surface. But, after the substrate is placed in clean air for about one day, residue was observed. It can be considered that organic compounds contained in slurry used during CMP or in washing liquid are left even after washing with alkaline chemicals or organic acid and subsequent drying. This residue may cause oxidation or decomposition of the copper wiring surface.

It is an object of the present invention to provide a semiconductor manufacturing method and apparatus capable of suppressing residues from being left on a substrate surface after CMP.

According to one aspect of the present invention, there is provided a manufacture method for a semiconductor device, comprising steps of: (a) washing a surface of a substrate with washing liquid, the substrate having an insulating region and a metal region exposed on the surface; and (b) irradiating an ultraviolet ray to the surface of the washed substrate.

According to another aspect of the present invention, there is provided a manufacture system comprising: wafer holder for rotatably holding a wafer; and an ultraviolet light source for irradiating an ultraviolet ray to a surface of the wafer held by the wafer holder.

Residues left on the surface of a substrate can be removed by irradiating an ultraviolet ray to the surface of the washed substrate.

### BRIEF DESCRIPTION OF THE DRAWINGS

FIGS. 1 to 3 are cross sectional views of a substrate illustrating a semiconductor manufacturing method according to an embodiment of the present invention.

FIG. 4 is a layout of a CMP apparatus and a washing apparatus used by the method of the embodiment.

FIG. 5 is a schematic cross sectional view of a drying apparatus used by the method of the embodiment.

FIG. 6 is a microscopic photograph showing the surface of a substrate exposing a copper wiring formed by the embodiment method.

FIG. 7 is a microscopic photograph showing the surface of a substrate exposing a copper wiring formed by a comparative method.

### BEST MODE FOR CARRYING OUT THE INVENTION

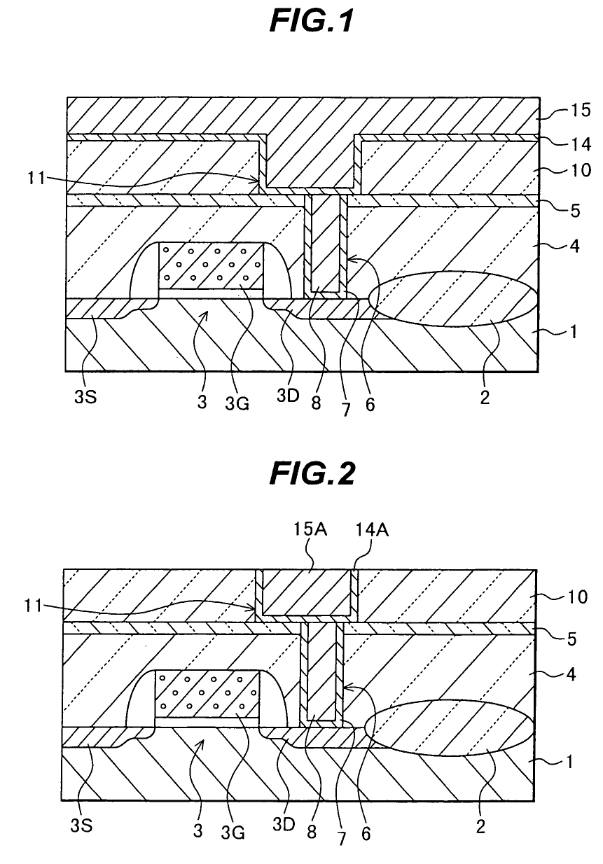

With reference to FIGS. 1 to 3, description will be made on a semiconductor manufacturing method according to an embodiment of the present invention.

As shown in FIG. 1, an active region is defined by an element isolation insulating film 2 formed on the surface of a semiconductor substrate 1 made of silicon. On the surface of the active region, a MOS transistor 3 is formed having a source region 3S, a drain region 3D and a gate electrode 3G.

An interlayer insulating film 4 made of phosphosilicate glass (PSG) is formed on the semiconductor substrate 1, covering the MOS transistor 3. The interlayer insulating film 4 is formed by depositing a PSG film to a thickness of 1.5 μm by chemical vapor deposition (CVD) at a substrate temperature of 600° C., followed by planarizing the surface thereof by chemical mechanical polishing (CMP).

A protective film 5 is formed on the interlayer insulating film 4, the protective film having a thickness of 50 nm and being made of silicon nitride. A via hole 6 is formed through the protective film 5 and interlayer insulating film 4, reaching the surface of the drain region 3D. The bottom and inner sidewall of the via hole 6 is covered with a barrier metal layer 7 of TiN or the like, and a conductive plug 8 of tungsten (W) or the like fills the via hole 6.

An insulating film 10 is formed on the protective film 5 by CVD using organic siloxane or the like as source gas, the insulating film having a thickness of about 100 to 2000 nm and being made of SiOC. A wiring trench 11 is formed through the insulating film 10, reaching the surface of the protective film 5. The upper surface of the conductive plug 8 is exposed on the bottom of the wiring trench 11.

A barrier metal layer 14 is formed by sputtering on the inner surface of the wiring trench and the upper surface of the insulating film 10, the barrier metal layer 14 having a thickness of 5 to 50 nm and being made of TaN or Ta. A copper seed layer is formed by sputtering on the surface of the barrier metal layer 14, and copper or copper alloy is electroplated to form a metal film 15. The inside of the wiring trench 11 is filled with the metal film 15.

As shown in FIG. 2, the metal film 15 and barrier metal layer 14 shown in FIG. 1 are subjected to chemical mechanical polishing until the insulating film 10 is exposed. A barrier metal layer 14A is left on the inner surface of the wiring trench 11, and a copper wiring 15A filling the wiring trench 11 is left.

After the chemical mechanical polishing, the substrate having the exposed surface of the insulating film 10 and copper wiring 15A are dipped in pre-processing liquid for 50 seconds. Dipping in the pre-processing liquid is called “pre-process”. For example, the pre-processing liquid is aqueous solution which contains benzotriazole (BTA) and tetramethylammonium hydroxide (TMAH). A concentration of BTA is 0.05 volume % and a concentration of TMAH is 0.2 volume %. BTA is anticorrosion agent for preventing corrosion of copper. A TMAH concentration of the pre-processing liquid may be 0.01 to 1.2 volume %. A BTA concentration may be 0.001 to 1.0 volume %. An ultrasonic process may be executed in the state that the substrate is dipped in the pre-processing liquid.

After the pre-process, the substrate surface is brushed with washing liquid. The washing liquid is an acid chemical which contain organic acid such as oxalic acid and citric acid. After brush washing, the substrate is dried with a spin rinse drier.

Ultraviolet rays are irradiated to the surface of the dried substrate. Ultraviolet rays may be irradiated after the substrate is dried with the spin rinse drier as in this embodiment or the drying process and ultraviolet ray irradiating process may be executed at the same time.

After ultraviolet rays are irradiated, the surface of the copper wiring 15A is reduced by using ammonium plasma or hydrogen plasma. If copper oxide is generated on the surface, the copper oxide is removed during this plasma process.

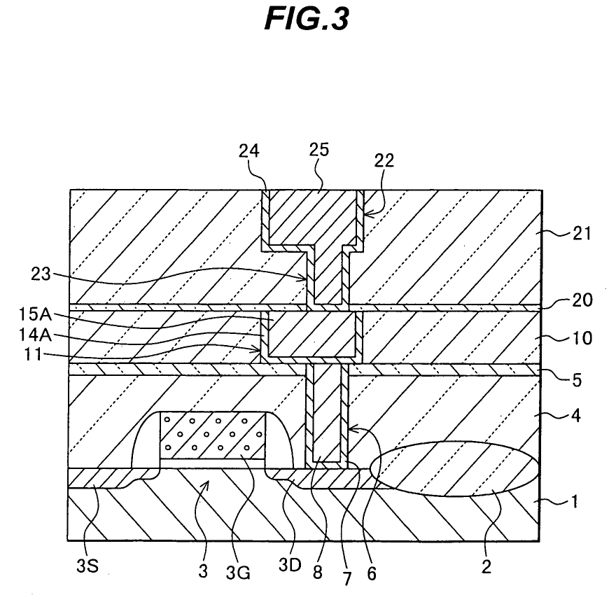

As shown in FIG. 3, an etching stopper film (diffusion preventing film) 20 and an interlayer insulating film 21 are sequentially formed on the insulating film 10 by CVD. The etching stopper film 20 is made of silicon nitride and has a thickness of 50 nm. The interlayer insulating film 21 is made of SiOC and has a thickness of about 100 to 2000 nm. A wiring trench 22 is formed reaching an intermediate depth of the interlayer insulating film 21 and a via hole 23 is formed in a partial bottom area of the wiring trench 22, reaching the upper surface of the underlying copper wiring 15A, by a well-known dual damascene method.

A barrier metal layer 24 of TaN or Ta is formed covering the bottom and inner side wall of the via hole 23 and the bottom and inner side wall of the wiring trench 22, and a copper wiring 25 is formed filling the inside of the via hole 23 and wiring trench 22. The barrier metal layer 24 and copper wiring 25 are formed by a method similar to the method of forming the barrier metal layer 14A and copper wiring 15A in the first layer. After the copper wiring 25 is formed, the substrate surface is washed, dried and irradiated with ultraviolet rays, similar to the processes executed after the copper wiring 15A in the first layer is formed.

A wiring in a third layer may be formed in a similar manner.

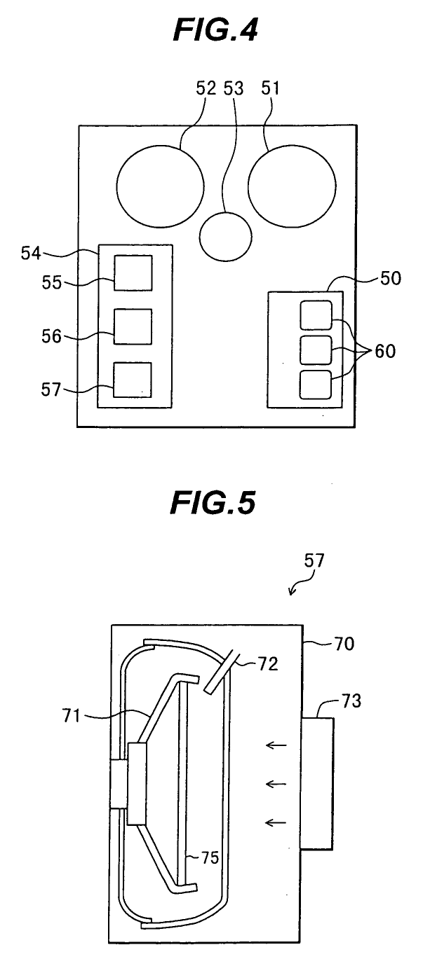

FIG. 4 shows the layout of a CMP apparatus, a washing apparatus and a drying apparatus. Detailed description will be made on a CMP process, a washing process and a drying process. A plurality of wafer cassettes 60 are placed at a wafer cassette installation site 50. Wafers, on which the metal film 15 shown in FIG. 1 is formed, is held in the wafer cassette 60.

The wafer held in the wafer cassette 60 is transported by a transport apparatus to a wafer delivery site 53. A wafer head receives the wafer transported to the wafer delivery site 53 and transports it to a copper polishing platen 51 whereat the copper film is polished and washed with water. The wafer head transports the wafer washed with water to a barrier metal polishing platen 52 whereat the barrier metal layer is polished and washed with water. The wafer washed with water is returned to the wafer delivery site 53.

The transport apparatus transports the wafer returned to the wafer delivery site 53 to a washing apparatus 54. An organic alkaline washing apparatus 55, an organic acid washing apparatus 56 and a spin rinse drier 57 are disposed in the washing apparatus 54. The organic alkaline washing apparatus 55 includes a processing bath being filled with chemicals are filled, the chemicals containing, for example, benzotriazole (BTA) and tetramethylammonium hydroxide (TMAH). A concentration of BTA is 0.05 volume % and a concentration of TMAH is 0.2 volume %. The organic acid washing apparatus 56 is a brush washing apparatus using organic acid such as oxalic acid and citric acid.

The wafer transported to the washing apparatus 54 is dipped in the chemicals in the organic alkaline washing apparatus 55. Thereafter, the wafer is subjected to brush washing using the organic acid in the organic acid washing apparatus 56. After the brush washing, the substrate is set to the spin rinse drier 57.

FIG. 5 is a schematic cross sectional view of the spin rinse drier 57. A wafer holding arm 71 is disposed in a container 70. The wafer holding arm 71 rotatably holds a wafer 75. A nozzle 72 jets out washing water to the surface of the wafer 75 held by the wafer holding arm 71. A xenon lamp 73 is mounted at the position facing the surface of the wafer 75 held by the wafer holding arm 71. The xenon lamp 73 emits ultraviolet rays containing light having a wavelength of 248 nm. A distance between the wafer 75 and xenon lamp 73 is about 10 cm.

When the wafer 75 is set to the spin rinse drier 57 after the brush washing with organic acid, the wafer 75 is washed with water while the wafer 75 is rotated and water is jetted out from the nozzle 72. Thereafter, jetting out water is stopped and the wafer 75 is spin-dried. After the spin-drying, an ultraviolet ray lamp 73 is turned on to irradiate ultraviolet rays to the wafer 75.

The transport apparatus returns the wafer 75 irradiated with ultraviolet rays to the wafer cassette at the wafer cassette installation site 50.

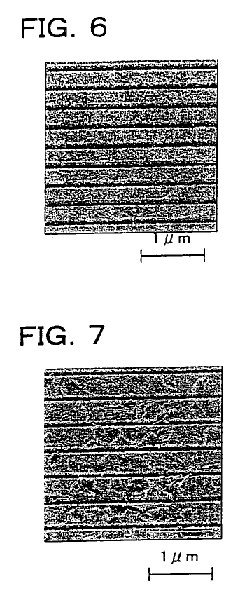

FIG. 6 shows a scanning electron microscope (SEM) photograph of a wafer surface, the wafer having copper wirings formed by the embodiment method, being subjected to washing, drying and ultraviolet ray irradiation and placed in clean air for about one day. The irradiation time of ultraviolet rays was set to 30 seconds.

Dense narrow lines in the photograph indicate insulating regions, and light thick lines indicate copper wirings. No residue was observed.

FIG. 7 is a SEM photograph of a wafer surface placed in clean air for about one day without performing ultraviolet ray irradiation. It can be seen that residues are left on the wafer surface. These residues are considered as the residues of organic compounds contained in the washing liquid.

It can be considered that residues are decomposed and the wafer surface is cleaned, by irradiating ultraviolet rays after drying as in the embodiment method.

In the above-described embodiment, although the xenon lamp is used for irradiating ultraviolet rays, other ultraviolet light sources may be used if they can irradiate ultraviolet rays in the wavelength range capable of decomposing organic residues. For example, a mercury lamp, a KrF lamp, a fluorescent lamp or the like may be used. If the wavelength of a ultraviolet ray is too short, semiconductor elements on a wafer are damaged. It is therefore preferable that an ultraviolet ray to be irradiated should not contain components having a wavelength shorter than 190 nm. As the wavelength is longer, organic residues are hard to be decomposed and an irradiation time is required to be prolonged. It is therefore preferable to set the wavelength of an ultraviolet ray to 190 to 400 nm.

An irradiation time of an ultraviolet ray is preferably set to 15 seconds or longer. At an irradiation time longer than 60 seconds, there is no large difference in the residue removing effects.

In the above-described embodiment, the surface washing and drying method has been described by using as an example a substrate having a copper wiring buried in an interlayer insulating film of SiOC. The washing and drying method of the embodiment is applicable to washing the surface of a substrate having a metal wiring made of metal other than copper buried in an interlayer insulating film made of different insulating material. The material of the interlayer insulating film may be, for example, SiLK (registered trademark of the Dow Chemical Company), SiO₂, fluorine-doped SiO₂ and the like. The wiring material may be alloy which contains copper as the main component.

In the above-described embodiment, the substrate surface after CMP is washed with TMAH or organic acid. If the substrate surface is washed with other organic washing liquid, the residue removing effects with ultraviolet ray irradiation can also be expected.

The present invention has been described in connection with the preferred embodiment. The invention is not limited only to the above embodiment. It will be apparent to those skilled in the art that other various modifications, improvements, combinations, and the like can be made.

1. A manufacture method for a semiconductor device, comprising steps of:
(a) washing a surface of a substrate with washing liquid, the substrate having an insulating region and a metal region exposed on the surface; and
(b) irradiating an ultraviolet ray to the surface of the washed substrate.

2. The manufacture method for a semiconductor device, according to claim 1, wherein the step (a) comprises:
forming a first insulating film on a surface of a semiconductor substrate having semiconductor elements formed on the surface;
forming a recess in the first insulating film;
depositing a metal film on the first insulating film, the recess being filled with the metal film; and
subjecting the metal film to chemical mechanical polishing until a surface of the first insulating film is exposed.

3. The manufacture method for a semiconductor device, according to claim 1, wherein the step (b) comprises:
washing the surface of the substrate with water; and
drying the substrate while an ultraviolet ray is irradiated to the surface of the substrate.

4. The manufacture method for a semiconductor device, according to claim 1, further comprising after the step (b):
executing a reduction process by exposing the surface of the substrate in a reducing atmosphere; and
forming a second insulating film on a reduced surface of the substrate.

5. The manufacture method for a semiconductor device, according to claim 1, wherein the metal region exposed on the surface of the substrate is a wiring made of copper or copper alloy.

6. The manufacture method for a semiconductor device, according to claim 1, wherein a wavelength range of the ultraviolet ray irradiated in the step (b) is longer than 190 nm.

7. A manufacture system comprising:
wafer holder for rotatably holding a wafer; and
an ultraviolet light source for irradiating an ultraviolet ray to a surface of the wafer held by the wafer holder.

8. The manufacture system according to claim 7, further comprising a nozzle for jetting out rinse liquid to the surface of the wafer held by the wafer holder.

9. The manufacture system according to claim 7, wherein the ultraviolet light source irradiates an ultraviolet ray having a wavelength longer than 190 nm.
